(19) United States
(12) Patent Application Publication
(10) Pub. No.: US 2024/0421080 A1
(43) Pub. Date: Dec. 19, 2024

(54) HIGH BANDWIDTH MEMORY STRUCTURE AND METHOD FOR MANUFACTURING THE SAME

(71) Applicant: SAMSUNG ELECTRONICS CO., LTD., Suwon-si (KR)

(72) Inventor: Youngbae Kim, Suwon-si (KR)

(21) Appl. No.: 18/438,167

(22) Filed: Feb. 9, 2024

(30) Foreign Application Priority Data
Jun. 14, 2023 (KR) 10-2023-0076195

(51) Int. Cl. H01L 23/528; H01L 21/66; H01L 25/065; H10B 80/00

(52) U.S. Cl. CPC H01L 23/5283; H01L 22/32; H01L 25/0657; H10B 80/00; H01L 2225/06513

(57) ABSTRACT

A high bandwidth memory structure according to an embodiment may include a buffer die including a plurality of conductive lines, a memory stacking structure on the buffer die, the memory stacking structure includes a plurality of memory dies that are stacked, an interconnection structure between the buffer die and the memory stacking structure, the interconnection structure includes a plurality of connection members and an insulating member surrounding the plurality of connection members, and a plurality of conductive pads disposed on the buffer die and side by side with the plurality of connection members, in which each conductive line of the plurality of conductive lines connect a connection member of the plurality of connection members to a conductive pad of the plurality of conductive pads.

### CROSS-REFERENCE TO RELATED APPLICATION

This application claims priority to and the benefit of Korean Patent Application No. 10-2023-0076195 filed in the Korean Intellectual Property Office on Jun. 14, 2023, the disclosure of which is incorporated herein by reference in its entirety.

### BACKGROUND OF THE INVENTION

The semiconductor industry is seeking to down-size, lighten, and thin semiconductor packages mounted in electronic devices, while simultaneously pursuing higher speed, multifunctionality, and increased storage, in response to the demand for down-sizing and lightening of electronic devices. Therefore, the need for a packaging technology capable of storing more data and transmitting data at a higher speed is increasing, and as such packaging technology, high bandwidth memory (HBM), which can achieve high levels of bandwidth by stacking more dynamic random access memories (DRAMs) on the same area of substrate is well known. A high bandwidth memory is manufactured by stacking a plurality of DRAMs in a manner of performing a bonding process between DRAMs. However, in the bonding process between DRAMs, when defects such as poor bonding between connection members, misalignment between connection members, or defects caused by particle generation occur, conventionally, these defects can only be determined at the final product stage, resulting in a deterioration in the yield of high bandwidth memory and an increase in manufacturing costs. Therefore, it is necessary to develop a new high bandwidth memory structure technology capable of improving these problems.

### SUMMARY OF THE INVENTION

In general, in some aspects, the present disclosure is directed toa high bandwidth memory structure and method for manufacturing the high bandwidth memory structure. In general, in some implementations, the memory structure includes conductive pads disposed on a buffer die, in which the conductive pads are electrically connected to connection members in order to test for defects that may occur in the connection members connecting a memory die and another memory die in a bonding process between the two memory dies.

According to some aspects of the present disclosure, a high bandwidth memory structure includes a buffer die including a plurality of conductive lines; a memory stacking structure on the buffer die, in which the memory stacking structure includes a plurality of memory dies that are stacked; an interconnection structure between the buffer die and the memory stacking structure, in which the interconnection structure includes a plurality of connection members and an insulating member surrounding the plurality of connection members; and a plurality of conductive pads disposed on the buffer die and adjacent to (e.g., side-by-side) the plurality of connection members. Each conductive line of the plurality of conductive lines connects a connection member of the plurality of connection members to a conductive pad of the plurality of conductive pads.

According to some aspects of the present disclosure, a high bandwidth memory includes a buffer die including a plurality of conductive lines; a memory stacking structure on the buffer die, in which the memory stacking structure includes a plurality of memory dies that are stacked; an interconnection structure between the buffer die and the memory stacking structure, in which the interconnection structure includes a plurality of connection members and an insulating member surrounding the plurality of connection members; a plurality of conductive pads disposed on the buffer die and adjacent to (e.g., side-by-side) the plurality of connection members, in which each conductive line of the plurality of conductive lines connects a connection member of the plurality of connection members to a conductive pad of the plurality of conductive pads; one or more heat dissipation structures are disposed on the buffer die and disposed adjacent to (e.g., side-by-side) the memory stacking structure; and a molding material disposed on the buffer die and molding the memory stacking structure and the one or more heat dissipation structures.

According to some aspects of the present disclosure, a method for manufacturing a high bandwidth memory structure includes: forming a plurality of test pads on a buffer die; stacking a first memory die among N memory dies on the buffer die using a plurality of first connection members, in which N is greater than or equal to 2, and the plurality of first connection members are disposed adjacent to (e.g., side-by-side) the plurality of test pads; testing whether a signal is transmitted to a first connection member corresponding to each test pad of the plurality of first connection members using each test pad of the plurality of test pads; stacking an n-th memory die on an n-1-th memory die using a plurality of n-th connection members; and testing whether a signal is transmitted through the n-th connection member corresponding to each of the test pads of the plurality of n-th connection members using each of the test pads of the plurality of test pads, where n is sequentially increased by 1 from 2 until n=N.

According to some aspects of the present disclosure, it is possible to provide a high bandwidth memory structure and a method for manufacturing a high bandwidth memory structure, in which conductive pads are disposed on a buffer die, and the conductive pads are electrically connected to connection members connecting a memory die and another memory die.

In a high bandwidth memory formed by stacking a plurality of memory dies, when a process of bonding a memory die and another memory die is performed, it is possible to test whether defects have occurred in the connection members connecting the two memory dies using the conductive pads disposed on the buffer die.

Since connection defects can be determined at an early stage so that measures for defects can be taken promptly, product production yield can be improved by reducing losses due to defects and preventing unnecessary further processing of devices having defective connections.

### BRIEF DESCRIPTION OF THE DRAWINGS

Exemplary implementations will be more clearly understood from the following detailed description, taken in conjunction with the accompanying drawings.

FIG. 1 is a cross-sectional view of an example high bandwidth memory according to some implementations.

FIG. 2 is a cross-sectional view of an example high bandwidth memory according to some implementations.

FIG. 3 is a cross-sectional view of an example high bandwidth memory according to some implementations.

FIG. 4 is a cross-sectional view of an example high bandwidth memory according to some implementations.

FIGS. 5 and 6 are top plan views illustrating a top surface of the high bandwidth memory of FIGS. 3 and 4.

FIGS. 7 to 14 are cross-sectional views illustrating an exemplary method for manufacturing the high bandwidth memory of FIG. 3 according to some implementations.

FIG. 15 is a cross-sectional view illustrating a 2.5D semiconductor package including the high bandwidth memories and a logic die of FIG. 3.

FIG. 16 is a top plan view illustrating a top surface of a 2.5D semiconductor package including the high bandwidth memories and the logic die of FIG. 3.

FIG. 17 is a cross-sectional view illustrating a 3D semiconductor package including the high bandwidth memories and the logic die of FIG. 3.

FIG. 18 is a top plan view illustrating a top surface of a 3D semiconductor package including the high bandwidth memories and the logic die of FIG. 3.

### DETAILED DESCRIPTION

Hereinafter, exemplary implementations will be described in detail with reference to the accompanying drawings.

The drawings and description are to be regarded as illustrative in nature and not restrictive. Like reference numerals designate like elements throughout the specification.

Size and thickness of each constituent element in the drawings are arbitrarily illustrated for better understanding and ease of description, the following embodiments are not limited thereto.

Throughout the specification, the term “connected” does not mean only that two or more constituent components are directly connected, but may also mean that two or more constituent components are indirectly connected through another constituent component. In addition, unless explicitly described to the contrary, the words “comprise” and “having”, and variations, such as “comprises,” “comprising,” “has,” or “have,” will be understood to imply the inclusion of stated elements but not the exclusion of any other elements.

It will be understood that when an element such as a layer, film, region, or substrate is referred to as being “on” or “above” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a high bandwidth memory structure 100, a method for manufacturing the high bandwidth memory structure 100, and semiconductor packages 300 and 400 including the high bandwidth memory structure 100 according to some implementations will be described with reference to the drawings.

High bandwidth memory (HBM) is a high performance three-dimensional (3D) stacked dynamic random-access memory RAM (DRAM). HBM is manufactured by performing hybrid bonding or by vertically stacking memory dies using micro bumps to form a single memory stack. HBM has multiple memory channels through a memory stack in which memory dies are vertically stacked, enabling shorter latency and higher bandwidth simultaneously compared to conventional DRAM products, and the total area occupied by individual DRAMs on the printed circuit board (PCB) can be reduced, which is advantageous for high bandwidth compared to the area and has the advantage of reducing power consumption.

Meanwhile, HBM is manufactured by stacking a plurality of DRAMs in a manner of performing a bonding process between DRAMs, and in the bonding process between the DRAMs, defects, such as poor bonding between connection members, misalignment between connection members, or defects caused by particle generation, may occur. However, if such a defect is determined at the final stage when the HBM is completed, even the portion of the HBM that is determined to be normal must be discarded together with the defective portion of the HBM, resulting in poorer yields and higher manufacturing costs for the HBM.

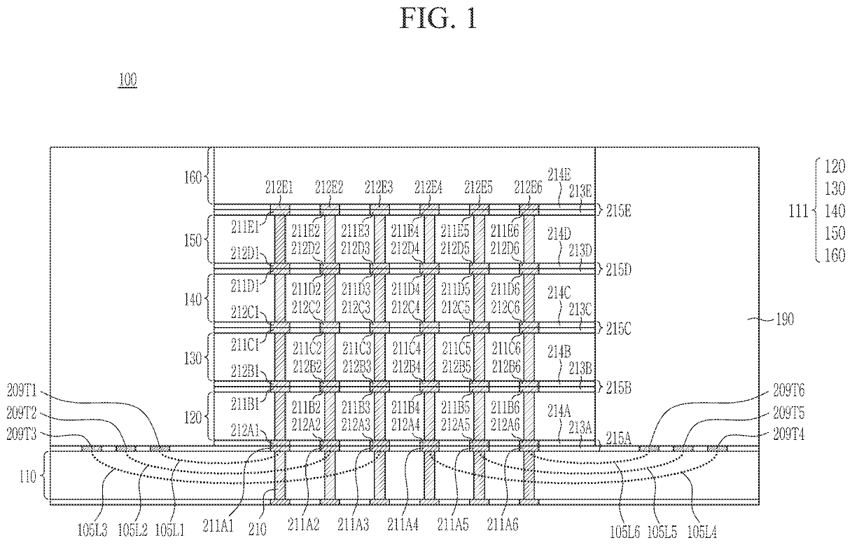

FIG. 1 is a cross-sectional view of a high bandwidth memory 100 according to some implementations.

In FIG. 1, the high bandwidth memory 100 includes a memory stacking structure 111 and conductive pads 209 disposed on a top surface of a buffer die 110. The memory dies 120, 130, 140, 150, and 160 of the memory stacking structure 111 are coupled by hybrid bonding, and the memory stacking structure 111 and the buffer die 110 are coupled by hybrid bonding. The high bandwidth memory 100 may include the buffer die 110, the memory stacking structure 111 including the memory dies 120, 130, 140, 150, and 160, a molding material 190, and the conductive pads 209. The buffer die 110 is disposed lowest in the high bandwidth memory 100 and may be disposed between the memory stacking structure 111 and an external device (not shown). When data is exchanged between devices having different data processing speeds, processing units, and usage times, data loss may occur due to differences in data processing speeds, processing units, and usage times between devices. In order to prevent this data loss, the buffer die 110 may be disposed between the memory stacking structure 111 and an external device (not shown), and when data is exchanged between the memory stacking structure 111 and an external device (not shown) information may be temporarily stored in the buffer die 110.

When sending data to or receiving data from the memory dies 120, 130, 140, 150, and 160, the buffer die 110 may sequence the data and pass the data sequentially.

The buffer die 110 may include conductive lines 105. The conductive lines 105 may include first conductive lines 105L1, second conductive lines 105L2, third conductive lines 105L3, fourth conductive lines 105L4, fifth conductive lines 105L5, and sixth conductive lines 105L6. The first conductive lines 105L1 may electrically connect a lower bonding pad 211A1 of a first interconnection structure 215A to a first conductive pad 209T1 disposed on a top surface of the buffer die 110. The second conductive lines 105L2 may electrically connect a lower bonding pad 211A2 of the first interconnection structure 215A to a first conductive pad 209T2 disposed on the top surface of the buffer die 110. The third conductive lines 105L3 may electrically connect a lower bonding pad 211A3 of the first interconnection structure 215A to a third conductive pad 209T3 disposed on the top surface of the buffer die 110. The fourth conductive lines 105L4 may electrically connect a lower bonding pad 211A4 of the first interconnection structure 215A to a fourth conductive pad 209T4 disposed on the top surface of the buffer die 110. The fifth conductive lines 105L5 may electrically connect a lower bonding pad 211A5 of the first interconnection structure 215A to a fifth conductive pad 209T5 disposed on the top surface of the buffer die 110. The sixth conductive lines 105L6 may electrically connect a lower bonding pad 211A6 of the first interconnection structure 215A to a sixth conductive pad 209T6 disposed on the top surface of the buffer die 110. In another embodiment, high bandwidth memories that include fewer or greater numbers of conductive lines are within the scope of the present disclosure.

The memory stacking structure 111 may be disposed on the buffer die 110. The memory stacking structure 111 may include memory dies 120, 130, 140, 150, and 160. The memory stacking structure 111 may be coupled to the buffer die 110 by hybrid bonding. In the memory stacking structure 111, each of the memory dies 120, 130, 140, 150, and 160 may be coupled to each other by hybrid bonding.

Hybrid bonding may be performed using an interconnection structure 215 between the buffer die 110 and the memory stacking structure 111, or between the memory dies 120, 130, 140, 150, and 160. Hybrid bonding includes bonding two devices by fusing the same materials of the two devices using the bonding properties of the same material. Here, hybrid means that two different types of bonding are made, for example, bonding two devices with a first type of metal-metal bonding and a second type of non-metal-non-metal bonding. Hybrid bonding makes it possible to form I/Os with a fine pitch.

The interconnection structure 215 may include lower bonding pads 211 and upper bonding pads 212 as connection members, and may include a lower silicon insulating layer 213 and an upper silicon insulating layer 214 as insulating members. The interconnection structure 215 may be defined as first to fifth interconnection structures 215A, 215B, 215C, 215D, and 215E from the bottom to the top according to positions.

The first interconnection structure 215A may include the lower bonding pads 211A1, 211A2, 211A3, 211A4, 211A5, and 211A6, upper bonding pads 212A1, 212A2, 212A3, 212A4, 212A5, and 212A6, a lower silicon insulating layer 213A, and an upper silicon insulating layer 214A. The second interconnection structure 215B may include lower bonding pads 211B1, 211B2, 211B3, 211B4, 211B5, and 211B6, upper bonding pads 212B1, 212B2, 212B3, 212B4, 212B5, and 212B6, a lower silicon insulating layer 213B, and an upper silicon insulating layer 214B. The third interconnection structure 215C may include lower bonding pads 211C1, 211C2, 211C3, 211C4, 211C5, and 211C6, upper bonding pads 212C1, 212C2, 212C3, 212C4, 212C5, and 212C6, a lower silicon insulating layer 213C, and an upper silicon insulating layer 214C. The fourth interconnection structure 215D includes lower bonding pads 211D1, 211D2, 211D3, 211D4, 211D5, and 211D6, upper bonding pads 212D1, 212D2, 212D3, 212D4, 212D5, and 212D6, a lower silicon insulating layer 213D, and an upper silicon insulating layer 214D. The fifth interconnection structure 215E may include lower bonding pads 211E1, 211E2, 211E3, 211E4, 211E5, and 211E6, upper bonding pads 212E1, 212E2, 212E3, 212E4, 212E5, and 212E6, a lower silicon insulating layer 213E, and an upper silicon insulating layer 214E. In some implementations, a high bandwidth memory includes fewer or more interconnection structures, lower bonding pads, upper bonding pads, lower silicon insulating layer, and upper silicon insulating layer.

The lower bonding pads 211 may be disposed on the top surface of the buffer die 110 or on the top surface of each of the memory dies 120, 130, 140, and 150. Upper bonding pads 212 may be disposed on the bottom surface of each of the memory dies 120, 130, 140, 150, and 160. The lower silicon insulating layer 213 may be disposed on the top surface of the buffer die 110 or on the top surface of each of the memory dies 120, 130, 140, and 150. The upper silicon insulating layer 214 may be disposed on a bottom surface of each of the memory dies 120, 130, 140, 150, and 160.

The lower bonding pad 211 may be directly bonded to the upper bonding pad 212 by metal-metal hybrid bonding, in which a metal bond is formed at an interface between the lower bonding pad 211 and the upper bonding pad 212. In some implementations, the lower bonding pad 211 and the upper bonding pad 212 include copper. In some implementations, the lower bonding pad 211 and the upper bonding pad 212 are a metallic material capable of hybrid bonding.

Since the lower bonding pad 211 and the upper bonding pad 212 are made of the same material, an interface between the lower bonding pad 211 and the upper bonding pad 212 may disappear after hybrid bonding. The buffer die 110 and the memory stacking structure 111 may be electrically connected to each other by the lower bonding pad 211 and the upper bonding pad 212. The memory dies 120, 130, 140, 150, and 160 may be electrically connected to each other by the lower bonding pad 211 and the upper bonding pad 212

The lower silicon insulating layer 213 may be directly bonded to the upper silicon insulating layer 214 by non-metal-non-metal hybrid bonding, in which a covalent bond is formed at an interface between the lower silicon insulating layer 213 and the upper silicon insulating layer 214.

In some implementations, the lower silicon insulating layer 213 and the upper silicon insulating layer 214 include silicon oxide or a TEOS forming oxide. In some implementations, the lower silicon insulating layer 213 and the upper silicon insulating layer 214 include SiO₂. In some implementations, the lower silicon insulating layer 213 and the upper silicon insulating layer 214 may be silicon nitride, silicon oxynitride, or other suitable dielectric material. In some implementations, the lower silicon insulating layer 213 and the upper silicon insulating layer 214 include SiN or SiCN.

Since the lower silicon insulating layer 213 and the upper silicon insulating layer 214 are made of the same material, an interface between the lower silicon insulating layer 213 and the upper silicon insulating layer 214 may disappear after hybrid bonding.

The memory dies 120, 130, 140, and 150 may each include memory channels (not shown) and through-silicon vias 210. A memory die 160 may include memory channels (not shown). In some implementations, memory dies 120, 130, 140, 150, and 160 each include DRAM. In some implementations, high bandwidth memories include fewer or greater numbers of memory dies.

For electrical coupling between the buffer die 110 and the memory dies 120, 130, 140, 150, and 160, the buffer die 110 and the memory dies 120, 130, 140, and 150 may include through-silicon vias 210, in which the uppermost memory die 160 may not include the through-silicon vias 210. The through-silicon vias 210 may be formed by drilling fine holes vertically penetrating each of the buffer die 110 and the memory dies 120, 130, 140, and 150, filling the holes with a conductive material, and connecting them with electrodes.

In some implementations, the holes of the through-silicon vias 210 are formed by a deep etching process. In some implementations, the holes of the through-silicon vias 210 are formed by a laser process. In some implementations, the holes of the through-silicon vias 210 are filled with a conducting material by using an electrolytic plating process. In some implementations, the through-silicon vias 210 include at least one of tungsten, aluminum, copper, and alloys thereof. In addition, a barrier layer (not shown) may be formed between the insulating material of the buffer die 110 and the through-silicon vias 210, and between the insulating material of the memory dies 120, 130, 140, 150, and 160 and the through-silicon vias 210. In some implementations, the barrier layer (not shown) includes at least one of titanium, tantalum, titanium nitride, tantalum nitride, or an alloy thereof.

The molding material 190 may be disposed on the buffer die 110 and mold the memory stacking structure 111. The molding material 190 may serve to protect and insulate the memory stacking structure 111. In some implementations, the molding material 190 is formed of a thermosetting resin, such as epoxy resin. In some implementations, the molding material 190 is an epoxy molding compound (EMC). In some implementations, the process of molding with the molding material 190 includes a compression molding process or a transfer molding process.

Conductive pads 209 may be disposed on a top surface of the buffer die 110. Side surfaces of the conductive pads 209 may be surrounded by a lower silicon insulating layer 213. The conductive pads 209 may include conductive pads 209T1, 209T2, 209T3, 209T4, 209T5, and 209T6, and the conductive pads 209 may be disposed at the same level as the lower bonding pads 211A1, 211A2, 211A3, 211A4, and 211A5. The conductive pads 209T1, 209T2, 209T3, 209T4, 209T5, and 209T6 may be physically connected to the conductive lines 105L1, 105L2, 105L3, 105L4, and 105L5, respectively.

The conductive pads 209 may include one or more electronic die sort (EDS) test pads. The EDS test is a process of contacting a probe card to an EDS test pad to deliver test signals, and determining whether a chip is defective or not implementing the test signal. A probe mark (PM) is formed on the top surface of the conductive pad 209, and the PM may have a shape of recess portion. According to some implementations, during the EDS test, it is possible to determine whether the lower bonding pad 211 and the upper bonding pad 212 of the interconnection structure 215 connected to the conductive line 105 are normally bonded by contacting the probe card to the conductive pad 209.

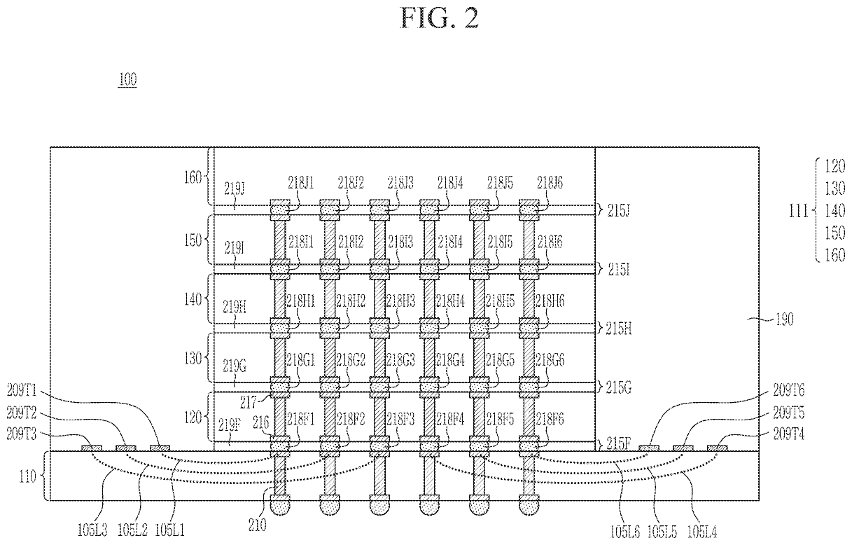

FIG. 2 is a cross-sectional view of the high bandwidth memory 100 according to some implementations. In FIG. 2, the high bandwidth memory 100 includes the memory stacking structure 111 and conductive pads 209 disposed on a top surface of a buffer die 110. The memory dies 120, 130, 140, 150, and 160 of the memory stacking structure 111, are coupled by flip chip bonding, and the memory stacking structure 111 and the buffer die 110 are coupled by flip chip bonding.

Referring to FIG. 2, the memory stacking structure 111 is disposed on the buffer die 110. The memory stacking structure 111 may include memory dies 120, 130, 140, 150, and 160, in which the memory stacking structure 111 may be coupled to the buffer die 110 by flip chip bonding. In the memory stacking structure 111, each of the memory dies 120, 130, 140, 150, and 160 may be coupled to each other by flip chip bonding.

The memory stacking structure 111 may be coupled to the buffer die 110 by the interconnection structure 215. In the memory stacking structure 111, each of the memory dies 120, 130, 140, 150, and 160 may be coupled to each other by the interconnection structure 215. The interconnection structure 215 may include connection members 218 and an insulating member 219. In some implementations, the connection members 218 include micro bumps. The insulating member 219 may be disposed between the buffer die 110 and the memory stacking structure 111 and between the memory dies 120, 130, 140, 150, and 160 to surround the connection members 218. Stress between the buffer die 110 and the memory stacking structure 111, as well as between the memory dies 120, 130, 140, 150, and 160, may be relieved by the insulating member 219. The insulating member 219 may include a non-conductive film (NCF).

The interconnection structure 215 may be defined as sixth to tenth interconnection structures 215F, 215G, 215H, 215I, and 215J from the bottom to the top positions. The sixth interconnection structure 215F may include connection members 218F1, 218F2, 218F3, 218F4, 218F5, and 218F6 and an insulating member 219F. The seventh interconnection structure 215G may include connection members 218G1, 218G2, 218G3, 218G4, 218G5, and 218G6 and an insulating member 219G. The eighth interconnection structure 215H may include connection members 218H1, 218H2, 218H3, 218H4, 218H5, and 218H6 and an insulating member 219H. The ninth interconnection structure 215I may include connection members 218I1, 218I2, 218I3, 218I4, 218I5, and 218I6 and an insulating member 219I. The tenth interconnection structure 215J may include connection members 218J1, 218J2, 218J3, 218J4, 218J5, and 218J6 and an insulating member 219J. In some implementations, a high bandwidth memory may include fewer or greater numbers of interconnection structures, connection members, and insulating members.

The memory dies 120, 130, 140, and 150 may each include a memory channel (not shown), first connection pads 216, through-silicon vias 210, and second connection pads 217. Each of the memory dies 160 may include a memory channel (not shown) and first connection pads 216. In some implementations, each of the memory dies 120, 130, 140, 150, and 160 may include a dynamic random access memory (DRAM).

The first connection pads 216 of the memory dies 120, 130, 140, and 150 may be disposed between the connection members 218 and the through-silicon vias 210. The first connection pads 216 of the memory dies 120, 130, 140, and 150 may electrically connect the through-silicon vias 210 to the connection members 218. The first connection pads 216 of the memory die 160 may be electrically connected to the connection members 218.

The through-silicon vias 210 may be disposed between the first connection pads 216 and the second connection pads 217. The through-silicon vias 210 may electrically connect the second connection pads 217 to the first connection pads 216. The second connection pads 217 may be disposed between the through-silicon vias 210 and the connection members 218. The second connection pads 217 may electrically connect the connection members 218 to the through-silicon vias 210.

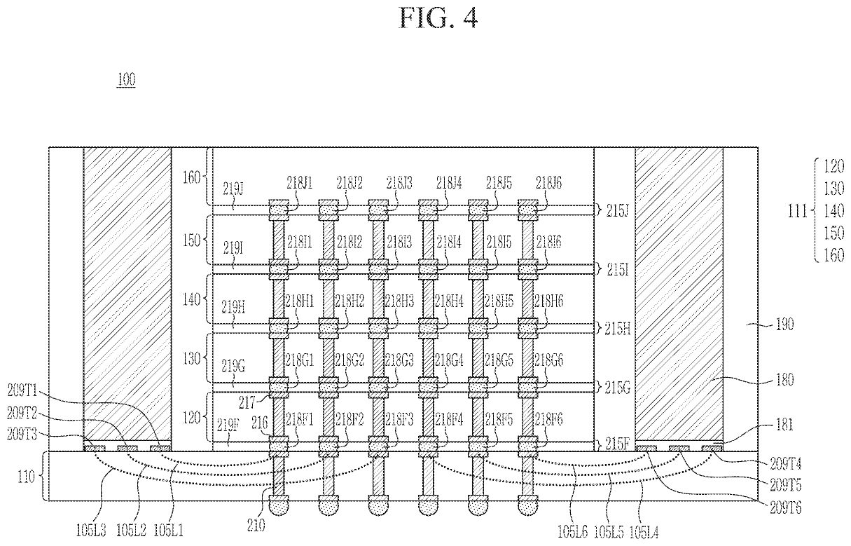

In FIG. 2, configurations other than the sixth to tenth interconnection structures 215F, 215G, 215H, 215I, and 215J, the first connection pads 216, and the second connection pads 217 are similar to the configuration described in FIG. 1. In FIG. 4, the elements described with respect to FIG. 1 may be similarly applied to configurations other than the sixth to tenth interconnection structures 215F, 215G, 215H, 215I, and 215J, the first connection pads 216, and the second connection pads 217.

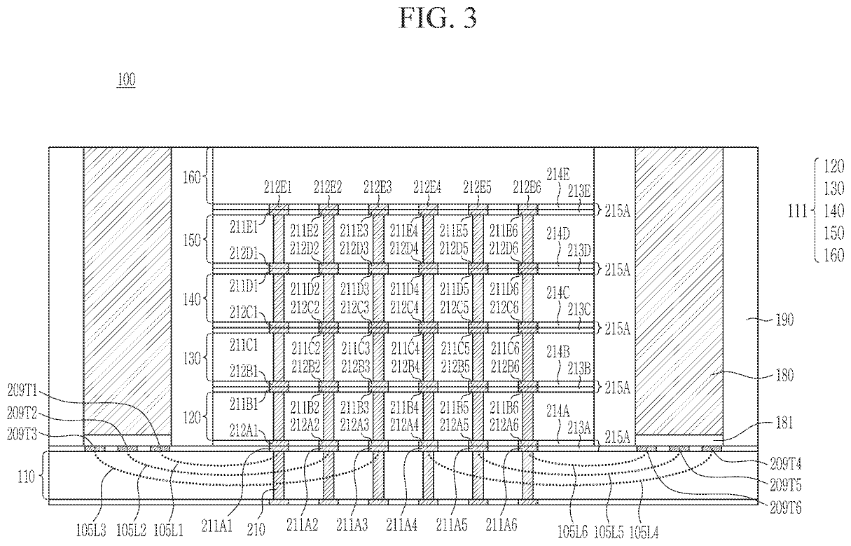

FIG. 3 is a cross-sectional view of the high bandwidth memory 100 according to some implementations. In FIG. 3, the high bandwidth memory 100 includes the memory stacking structure 111 and conductive pads 209 disposed on the top surface of the buffer die 110, and one or more heat dissipation structures 180 disposed on the conductive pads 209 and disposed adjacent to (e.g., side-by-side) the memory stacking structure 111. The memory dies 120, 130, 140, 150, and 160 of the memory stacking structure 111, are coupled by hybrid bonding, and the memory stacking structure 111 and the buffer die 110 are coupled by hybrid bonding.

Referring to FIG. 3, the high bandwidth memory 100 includes one or more heat dissipation structures 180 that are disposed on the conductive pads 209 and a lower silicon insulating layer 213, and may be disposed adjacent to (e.g., side-by-side) the memory stacking structure 111. In some implementations, one or more heat dissipation structures 180 are disposed to be spaced apart from the memory stacking structure 111, in which side surfaces of the one or more heat dissipation structures 180 may be surrounded by the molding material 190, and top surfaces of the one or more heat dissipation structures 180 may be exposed to the outside. In some implementations, the heat dissipation structure 180 is attached to the conductive pads 209 on the top surface of the buffer die 110 and on the lower silicon insulating layer 213 by an adhesive member 181.

The heat dissipation structure 180 may include a dummy die manufactured from a bare wafer. In some implementations, the heat dissipation structure 180 includes a crystalline silicon structure. An epoxy molding compound (EMC), which is a main material of the molding material 190, may have a thermal conductivity of about 0.3 W/mK to about 1.0 W/mK. In comparison, the thermal conductivity of silicon is about 83.7 W/mK, which is greater than the thermal conductivity of the molding material 190. Compared to the configuration where the memory stacking structure 111 is molded without the heat dissipation structure 180, when the heat dissipation structure 180 includes silicon and is formed within the molding material 190, the heat generated by the high bandwidth memory 100 can be effectively dissipated by the heat dissipation structure 180.

In some implementations, the heat dissipation structure 180 includes a heat slug, which may be referred to as a heat sink or a heat spreader and include a metal material having high thermal conductivity, such as copper or aluminum. Compared to the configuration where the memory stacking structure 111 is molded without the heat dissipation structure 180, when the heat dissipation structure 180 including the heat slug is formed within the molding material 190, the heat generated by the high bandwidth memory 100 can be effectively dissipated by the heat dissipation structure 180.

In the high bandwidth memory 100, heat may be accumulated on a side surface of the memory stacking structure 111 and a top surface of the buffer die 110, which are portions in contact with the molding material 190. Accordingly, the heat dissipation structure 180 may be positioned at a position spaced apart from the side surface of the memory stacking structure 111 and on the conductive pads 209 disposed on the top surface of the buffer die 110 to dissipate the heat accumulated on the side surface of the memory stacking structure 111 and on the top surface of the buffer die 110.

In some implementations, one side (bottom surface) of the heat dissipation structure 180 physically contacts the top surface of the conductive pads 209, and the other side (top surface) of the heat dissipation structure 180 may be exposed to the outside. Accordingly, heat accumulated on the top surface of the buffer die 110 may be conducted to one side (bottom surface) of the heat dissipation structure 180 physically contacting the top surface of the conductive pads 209, pass through the heat dissipation structure 180, and dissipate to the outside through the other side (top surface) of the heat dissipation structure 180. In addition, heat accumulated on the side surface of the memory stacking structure 111 may be conducted to the side surface of the heat dissipation structure 180 spaced apart by the molding material 190, pass through the heat dissipation structure 180, and dissipate to the outside through the other side (top surface) of the heat dissipation structure 180. In addition, the heat in the memory stacking structure 111 may be dissipated to the outside through the conductive lines 105 connected to the memory stacking structure 111, conductive pads 209 connected to the conductive line 105, and one or more heat dissipation structure 180 connected to the conductive pads 209.

In FIG. 3, configurations other than the heat dissipation structure 180 are similar to those described for FIG. 1. Therefore, the elements described for FIG. 1 may be equally applied to configurations other than the heat dissipation structure 180 in FIG. 3.

FIG. 4 is a cross-sectional view of a high bandwidth memory 100 of some implementations. In FIG. 4, the high bandwidth memory 100 includes the memory stacking structure 111 and conductive pads 209 disposed on the top surface of the buffer die 110, and one or more heat dissipation structures 180 disposed on the conductive pads 209 and disposed adjacent to (e.g., side-by-side) the memory stacking structure 111. The memory dies 120, 130, 140, 150, and 160 of the memory stacking structure 111, are coupled by flip chip bonding, and the memory stacking structure 111 and the buffer die 110 are coupled by flip chip bonding.

Referring to FIG. 4, the high bandwidth memory 100 may include one or more heat dissipation structures 180, which may be disposed on the buffer die 110 to surround the conductive pads 209. The adhesive member 181 may be disposed between the buffer die 100 and one or more heat dissipation structures 180, and between the conductive pads 209 and one or more heat dissipation structures 180.

In FIG. 4, configurations other than the heat dissipation structure 180 are similar to those described for FIG. 2, and the other features of the heat dissipation structure 180 and the adhesive member 181 other than the arrangement of the heat dissipation structure 180 and the adhesive member 181 described above are similar to the features described in FIG. 3.

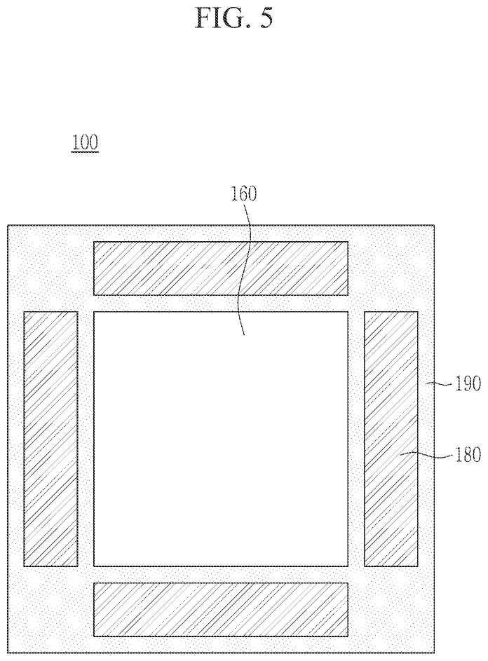

FIG. 5 is a top plan view illustrating a top surface of the high bandwidth memory 100 including heat dissipation structures 180 disposed adjacent to (e.g., side-by-side) the memory stacking structure 111. In FIG. 5, the heat dissipation structures 180 are disposed around a perimeter of the memory die 160 at the top of the memory stacking structure 111 and spaced apart from the memory die 160.

According to some implementations, the heat dissipation structures 180 are shown having a rectangular geometry, but are not limited thereto and may include various geometric shapes. In addition, according to some implementations, while one heat dissipation structure 180 is shown disposed next to each side of the memory die 160, a plurality of heat dissipation structures 180 may be disposed per side of the memory die 160.

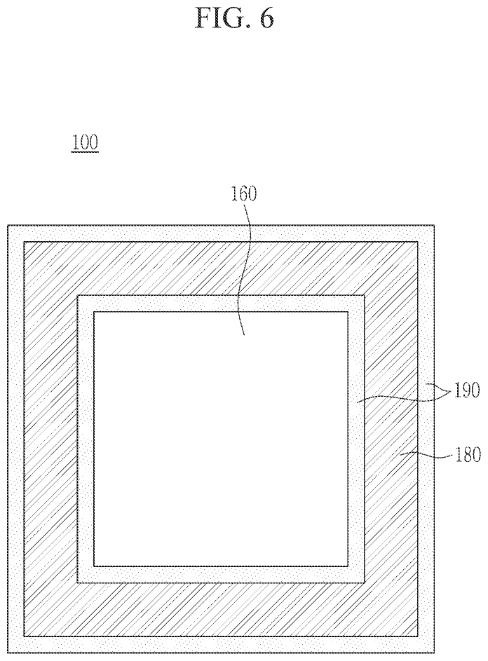

FIG. 6 is a top plan view illustrating a top surface of the high bandwidth memory 100 including the heat dissipation structure 180 surrounding the memory stacking structure 111. In FIG. 6, the heat dissipation structure 180 may surround side surfaces of the memory die 160 disposed to the top of the memory stacking structure 111 and may be spaced apart from the memory die 160. According to some implementations, one heat dissipation structure 180 continuously surrounds all side surfaces of the memory die 160 disposed to the top of the memory stacking structure 111. In some implementations one heat dissipation structure 180 surrounds one or more side surfaces of the memory die 160 disposed to the top of the memory stacking structure 111. In some implementations, the plurality of heat dissipation structures 180 surround one or more side surfaces of the memory die 160 disposed to the top of the memory stacking structure 111.

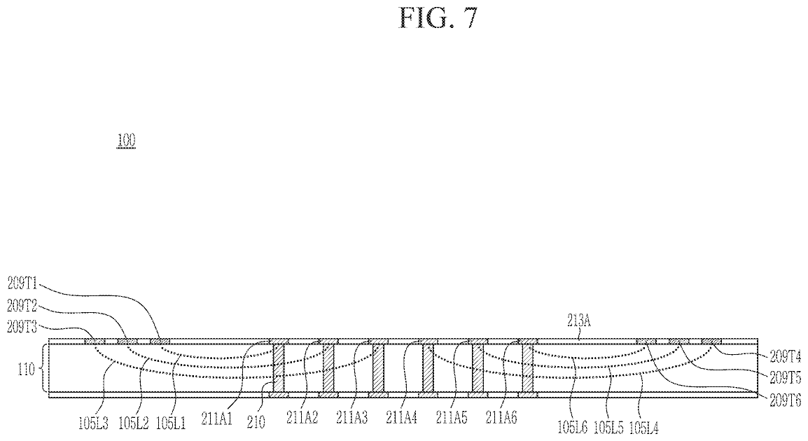

FIGS. 7 to 14 are cross-sectional views illustrating an exemplary method for manufacturing the high bandwidth memory 100 of FIG. 3. In FIGS. 7 to 14, the method for manufacturing the high bandwidth memories 100 of FIG. 3 is shown. However, processes of the manufacturing method of FIGS. 7 to 14 may also be applied to a method for manufacturing the high bandwidth memories 100 of FIGS. 1, 2, and 4.

In FIG. 7, the buffer die 110 is provided, and conductive pads 209, lower bonding pads 211, and a lower silicon insulating layer 213 are formed on a top surface of the buffer die 110. In some implementations, the buffer die 110 comprises conductive lines 105 electrically connecting the conductive pads 209 and lower bonding pads 211.

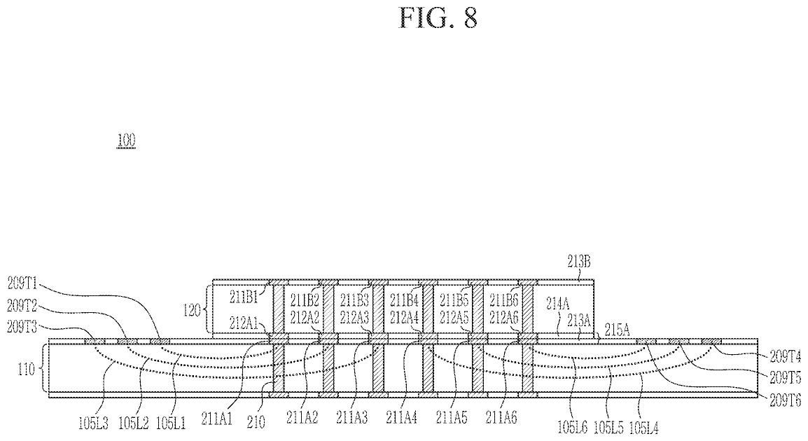

FIG. 8 is a cross-sectional view illustrating an exemplary operation of bonding the memory die 120 on the buffer die 110, and testing to determine whether or not the bonds between the memory die 120 and the buffer die 110 are defective.

In FIG. 8, the memory die 120 is bonded on the buffer die 110 by hybrid bonding. The lower bonding pads 211 of the buffer die 110 and the upper bonding pads 212 of the memory die 120 are directly bonded by metal-metal hybrid bonding. The lower silicon insulating layer 213 of the buffer die 110 and the upper silicon insulating layer 214 of the memory die 120 are directly bonded by non-metal-non-metal hybrid bonding.

After bonding is completed, the EDS test is performed by contacting the probe to the conductive pads 209. Specifically, by performing the EDS test on the conductive pads 209T1, 209T2, 209T3, 209T4, 209T5, and 209T6, a determination can be made whether there are bonding defects in the lower bonding pads 211A1, 211A2, 211A3, 211A4, 211A5, and 211A6 and upper bonding pads 212A1, 212A2, 212A3, 212A4, 212A5 and 212A6 connected to each of the conductive pads 209T1, 209T2, 209T3, 209T4, 209T5, and 209T6 through each of the conductive lines 105L1, 105L2, 105L3, 105L4, 105L5, and 105L6.

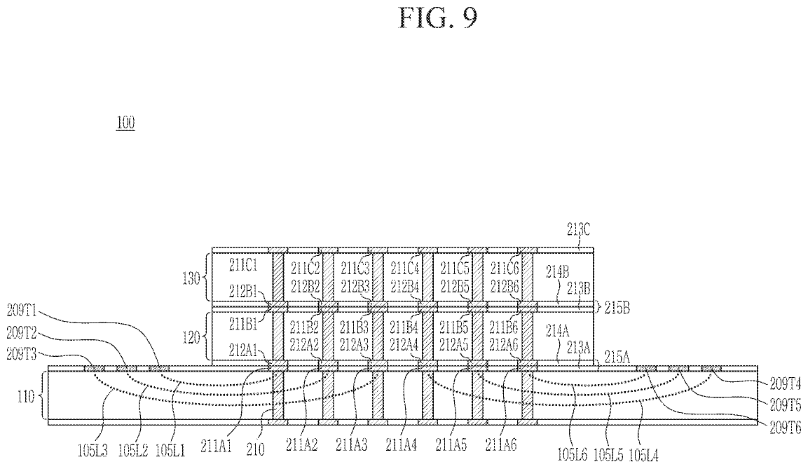

FIG. 9 is a cross-sectional view illustrating an exemplary operation of bonding the memory die 130 on the memory die 120, and testing to determine whether or not the bonds between the memory die 130 and the memory die 120 are defective. In FIG. 9, the memory die 130 is bonded on the memory die 120 by hybrid bonding. The lower bonding pads 211 of the memory die 120 and the upper bonding pads 212 of the memory die 130 are directly bonded by metal-metal hybrid bonding. The lower silicon insulating layer 213 of the memory die 120 and the upper silicon insulating layer 214 of the memory die 130 are directly bonded by non-metal-non-metal hybrid bonding.

After bonding is completed, the EDS test is performed by contacting the probe to the conductive pads 209. Specifically, by performing the EDS test on the conductive pads 209T1, 209T2, 209T3, 209T4, 209T5, and 209T6, a determination can be made whether there are bonding defects in the lower bonding pads 211B1, 211B2, 211B3, 211B4, 211B5, and 211B6 and upper bonding pads 212B1, 212B2, 212B3, 212B4, 212B5 and 212B6 connected to each of the conductive pads 209T1, 209T2, 209T3, 209T4, 209T5, and 209T6 through each of the conductive lines 105L1, 105L2, 105L3, 105L4, 105L5, and 105L6, and the through-silicon vias 210.

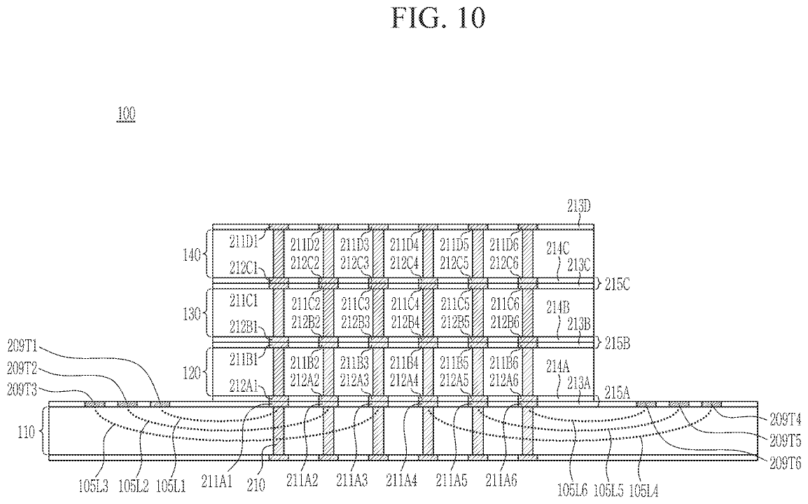

FIG. 10 is a cross-sectional view illustrating an exemplary operation of bonding the memory die 140 on the memory die 130, and testing to determine whether or not the bonds between the memory die 140 and the memory die 130 are defective. In FIG. 10, the memory die 140 is bonded on the memory die 130 by hybrid bonding. The lower bonding pads 211 of the memory die 130 and the upper bonding pads 212 of the memory die 140 are directly bonded by metal-metal hybrid bonding. The lower silicon insulating layer 213 of the memory die 130 and the upper silicon insulating layer 214 of the memory die 140 are directly bonded by non-metal-non-metal hybrid bonding.

After bonding is completed, the EDS test is performed by contacting the probe to the conductive pads 209. Specifically, by performing the EDS test on the conductive pads 209T1, 209T2, 209T3, 209T4, 209T5, and 209T6, a determination can be made whether there are bonding defects in the lower bonding pads 211C1, 211C2, 211C3, 211C4, 211C5, and 211C6 and the upper bonding pads 212C1, 212C2, 212C3, 212C4, 212C5 and 212C6 connected to each of the conductive pads 209T1, 209T2, 209T3, 209T4, 209T5, and 209T6 through each of the conductive lines 105L1, 105L2, 105L3, 105L4, 105L5, and 105L6, and the through-silicon vias 210.

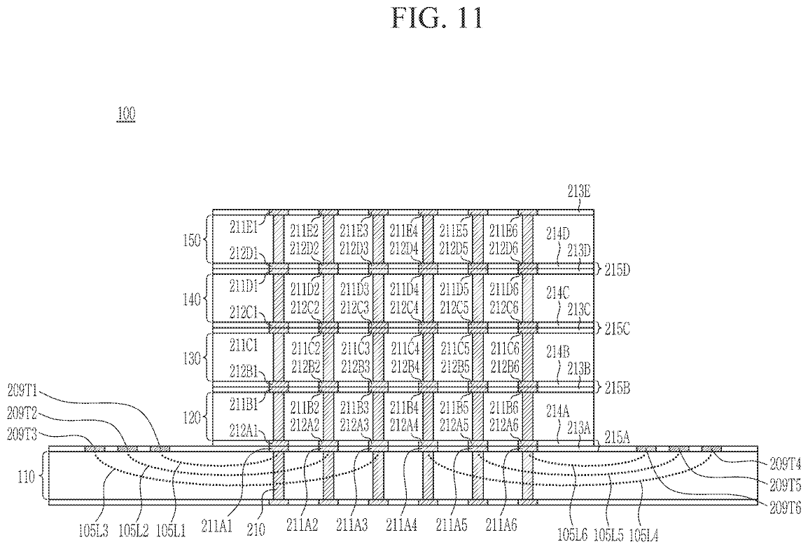

FIG. 11 is a cross-sectional view illustrating an exemplary operation of bonding the memory die 150 on the memory die 140, and testing to determine whether or not the bonds between the memory die 150 and the memory die 140 are defective. In FIG. 11, the memory die 150 is bonded on the memory die 140 by hybrid bonding. The lower bonding pads 211 of the memory die 140 and the upper bonding pads 212 of the memory die 150 are directly bonded by metal-metal hybrid bonding. The lower silicon insulating layer 213 of the memory die 140 and the upper silicon insulating layer 214 of the memory die 150 are directly bonded by non-metal-non-metal hybrid bonding.

After bonding is completed, the EDS test is performed by contacting the probe to the conductive pad 209. Specifically, by performing the EDS test on the conductive pads 209T1, 209T2, 209T3, 209T4, 209T5, and 209T6, a determination can be made whether there are bonding defects in the lower bonding pads 211D1, 211D2, 211D3, 211D4, 211D5, and 211D6 and the upper bonding pads 212D1, 212D2, 212D3, 212D4, 212D5 and 212D6 connected to the each of conductive pads 209T1, 209T2, 209T3, 209T4, 209T5, and 209T6 through each of the conductive lines 105L1, 105L2, 105L3, 105L4, 105L5, and 105L6, and the through-silicon vias 210.

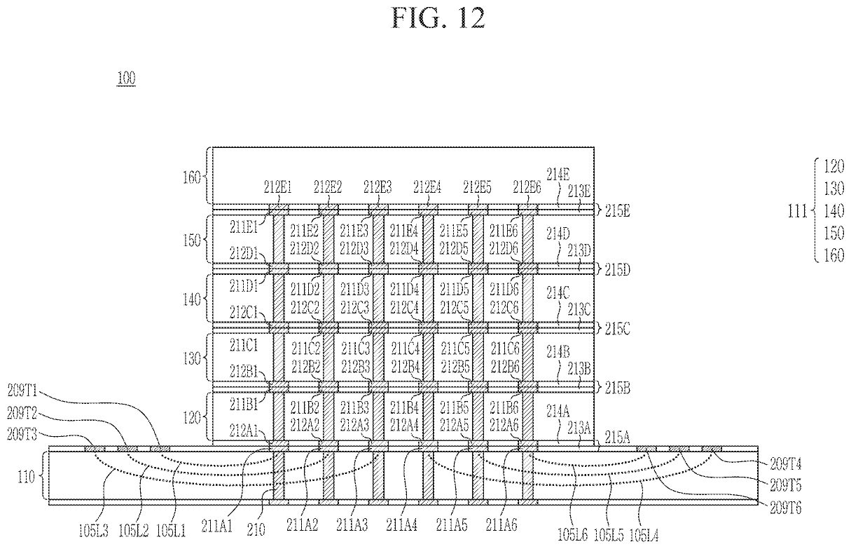

FIG. 12 is a cross-sectional view illustrating an exemplary operation of bonding the memory die 160 on the memory die 150, and testing to determine whether or not the bonds between the memory die 160 and the memory die 150 are defective. In FIG. 12, the memory die 160 is bonded on the memory die 150 by hybrid bonding. The lower bonding pads 211 of the memory die 150 and the upper bonding pads 212 of the memory die 160 are directly bonded by metal-metal hybrid bonding. The lower silicon insulating layer 213 of the memory die 150 and the upper silicon insulating layer 214 of the memory die 160 are directly bonded by non-metal-non-metal hybrid bonding.

After bonding is completed, the EDS test is performed by contacting the probe to the conductive pads 209. Specifically, by performing the EDS test on the conductive pads 209T1, 209T2, 209T3, 209T4, 209T5, and 209T6, a determination can be made whether there are bonding defects in the lower bonding pads 211E1, 211E2, 211E3, 211E4, 211E5, and 211E6 and the upper bonding pads 212E1, 212E2, 212E3, 212E4, 212E5 and 212E6 connected to each of the conductive pads 209T1, 209T2, 209T3, 209T4, 209T5, and 209T6 through each of the conductive lines 105L1, 105L2, 105L3, 105L4, 105L5, and 105L6, and the through-silicon vias 210.

According to some implementations, whenever a separate process of bonding the memory dies 120, 130, 140, 150, and 160 is performed, it is possible to test whether there are defects, such as poor bonding between the connection members connecting the memory dies 120, 130, 140, 150, and 160, misalignment between the connection members, or defects due to particle generation at positions of the connection members using the conductive pads 209 disposed on the buffer die 110. Since connection defects can be determined at an early stage so that remediating measures for detects defects can be taken promptly, product production yield can be improved by reducing losses due to detected defects and preventing unnecessary further processing of devices having the defective connections.

In some implementations, methods for manufacturing high bandwidth memory may include stacking and testing fewer or greater numbers of memory dies than those discussed above.

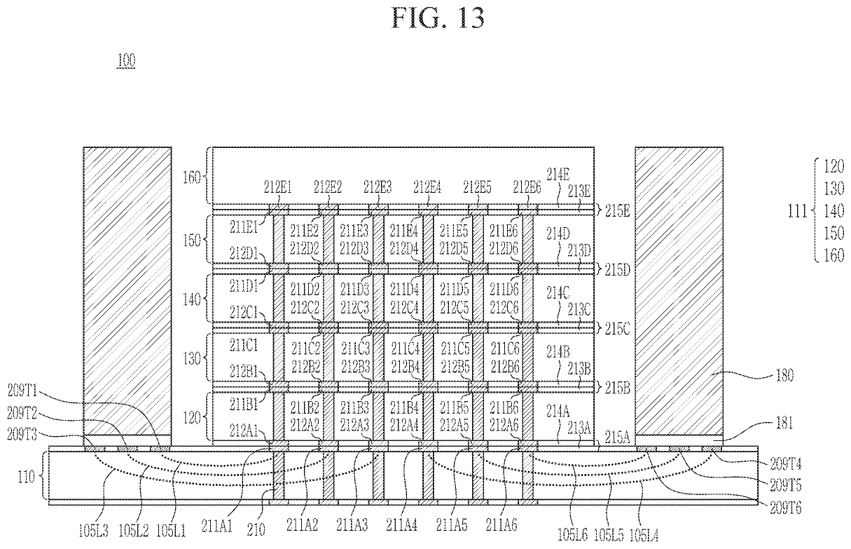

FIG. 13 is a cross-sectional view illustrating an exemplary operation of forming a heat dissipation structure on the conductive pads 209 and the lower silicon insulating layer 213. In FIG. 13, the heat dissipation structure 180 is attached to the conductive pads 209 on the top surface of the buffer die 110 and on the lower silicon insulating layer 213 by the adhesive member 181. In some implementations in which the heat dissipation structure 180 is a silicon structure, the adhesive member 181 includes a die attach film (DAF), adhesive tape, Ag paste, epoxy resin, or polyimide.

In some implementations in which the heat dissipation structure 180 is a heat slug, the adhesive member 181 includes a thermal interface material (TIM), in which a material is interposed to improve thermal coupling between a device that dissipates heat (e.g., buffer die 110) and the heat dissipation structure 180. The TIM serves to reduce thermal contact resistance by filling the air layer of the contact surface between the heat generating device and the heat dissipation device. In some implementations, the TIM includes a thermal paste, a thermal pad, a phase change material (PCM), or a metal material. In some implementations, the TIM includes grease.

In some implementations where the heat dissipation structure 180 is a silicon structure, the heat dissipation structure 180 is formed by CVD. In some implementation where the heat dissipation structure 180 is a heat slug, the heat dissipation structure 180 is formed by PVD.

In some implementations for forming the heat dissipation structure 180, the memory laminated structure 111 may be first molded on the buffer die 110 with the molding material 190, and then a photoresist application, exposure, development, etching, and deposition process may be performed to form the heat dissipation structure 180 within the molding material 190. In Accordingly, the heat dissipation structure 180 may be formed without use of the adhesive member 181.

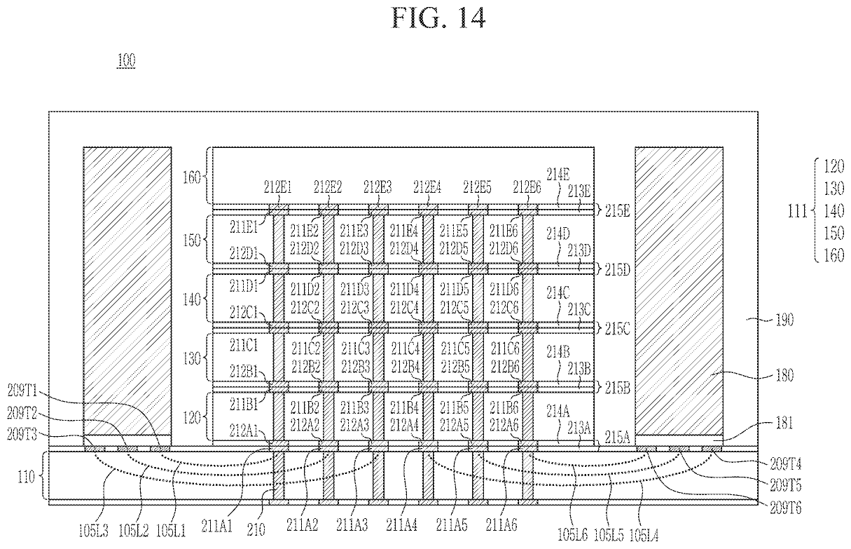

FIG. 14 is a cross-sectional view illustrating an exemplary operation of molding the memory stacking structure 111 and one or more heat dissipation structures 180 with the molding material 190 on the conductive pads 209 and the lower silicon insulating layer 213. In FIG. 14, the memory stacked structure 111 and one or more heat dissipation structures 180 are molded with the molding material 190 on the conductive pads 209 and on the lower silicon insulating layer 213, on the top surface of the buffer die 110. In some implementations, the process of molding with the molding material 190 includes a compression molding process or a transfer molding process. In some implementations, the molding material 190 is formed of a thermosetting resin, such as epoxy resin. In some implementations, the molding material 190 is an epoxy molding compound (EMC).

Next, a chemical mechanical planarization (CMP) process may be performed on the molding material 190 to expose the top surfaces of the memory stacking structure 111 and the top surfaces of the one or more heat dissipation structures 180.

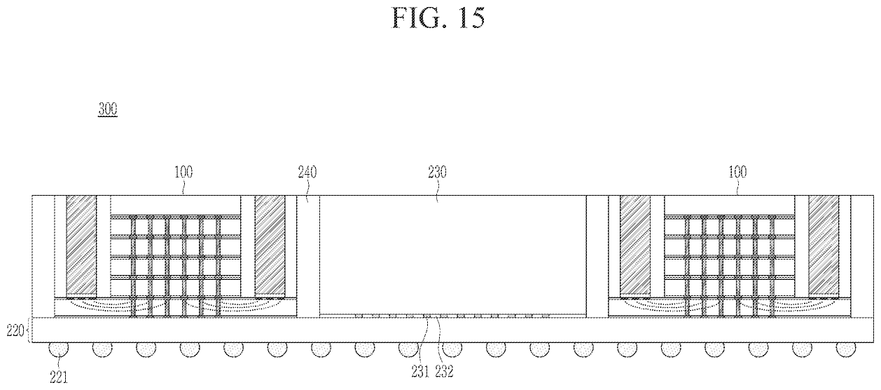

FIG. 15 is a cross-sectional view illustrating a 2.5D semiconductor package 300 including the high bandwidth memories 100 of FIG. 3 and a logic die 230. Although only the high bandwidth memories 100 of FIG. 3 are shown, the high bandwidth memories 100 of FIGS. 1, 2, and 4 may also be implemented in FIG. 15 in a similar way as replacing the high bandwidth memory 100 of FIG. 1.

In FIG. 15, the 2.5D semiconductor package 300 includes an interposer 220, the high bandwidth memories 100, the logic die 230, and a molding material 240. A substrate (not shown) may be disposed below the interposer 220, and connection members 221 may be disposed on the bottom surface of the interposer 220. In some implementations, the interposer 220 includes a silicon interposer.

In FIG. 15, the high bandwidth memories 100 and the logic die 230 may be disposed on the interposer 220, in which the high bandwidth memories 100 and the logic die 230 may be coupled with the interposer 220 by hybrid bonding. The logic die 230 may include bonding pads 231 and a silicon insulating layer 232 for hybrid bonding. Here, the bonding pads and the silicon insulating layer of the interposer 220, which are coupled to the bonding pads 231 and the silicon insulating layer 232 by hybrid bonding, are omitted. The hybrid bonding described for FIG. 1 may be equally applied to the hybrid bonding for FIG. 15.

The logic die 230 may be disposed adjacent to (e.g., side-by-side) the high bandwidth memories 100 between the high bandwidth memories 100. In some implementations, the logic die 230 includes a system on chip (SoC). In some implementations, the logic die 230 includes a central processing unit (CPU) or a graphic processing unit (GPU).

The molding material 240 may be disposed on the interposer 220 and may mold the high bandwidth memories 100 and the logic die 230, in which the molding material 240 may serve to protect and insulate the high bandwidth memories 100 and the logic die 230. In some implementations, the molding material 240 is formed of a thermosetting resin, such as epoxy resin. In some implementations, the molding material 240 is an epoxy molding compound (EMC). In some implementations, the process of molding with the molding material 240 includes a compression molding process or a transfer molding process.

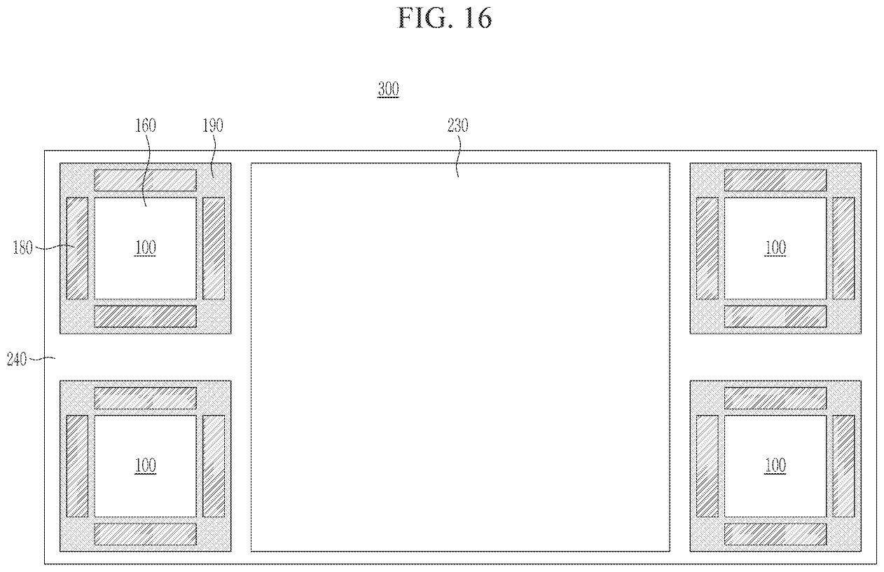

FIG. 16 is a top plan view illustrating a top surface of the 2.5D semiconductor package 300 including the high bandwidth memories 100 and the logic die 230. In FIG. 16, the high bandwidth memories 100 including the heat dissipation structures 180 are disposed around a perimeter of the logic die 230. As such, by disposing the heat dissipation structures 180 on the buffer die 110 of the high bandwidth memory 100, the thermal conductivity of the high bandwidth memory 100 may be improved, and the heat generated by the high bandwidth memory 100 may be more easily dissipated. Accordingly, it is possible to improve thermal characteristics of the 2.5D semiconductor package 300 including the high bandwidth memory 100.

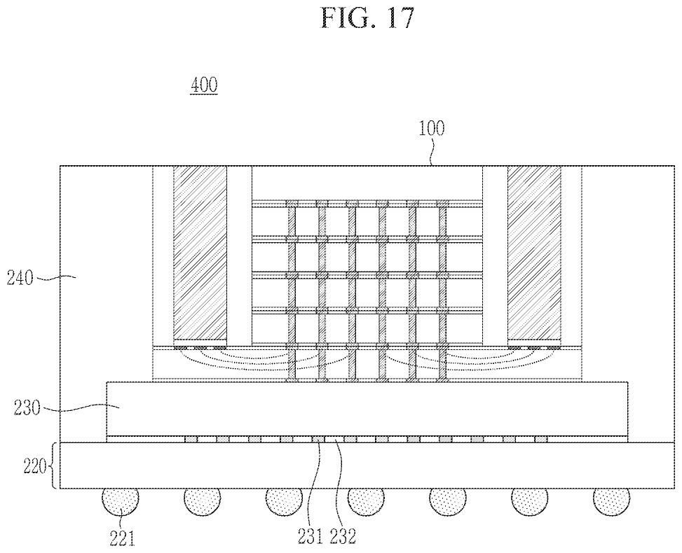

FIG. 17 is a cross-sectional view illustrating a 3D semiconductor package 400 including the high bandwidth memory 100 and the logic die 230 of FIG. 3. Although only the high bandwidth memory 100 of FIG. 3 is shown, the high bandwidth memory 100 of FIGS. 1, 2, and 4 may also be included in FIG. 17 in a similar way as replacing the high bandwidth memory 100 of FIG. 3.

In FIG. 17, the 3D semiconductor package 400 may include the interposer 220, the high bandwidth memory 100, the logic die 230, and the molding material 240. A substrate (not shown) may be disposed below the interposer 220, and connection members 221 may be disposed on the bottom surface of the interposer 220. In some implementation, the interposer 220 includes a silicon interposer.

The logic die 230 may be disposed on the interposer 220, and may be coupled to the interposer 220 by hybrid bonding. The hybrid bonding described for FIG. 1 may be equally applied to the hybrid bonding for FIG. 17. In some implementations, the logic die 230 includes a system on chip (SoC). In some implementations, the logic die 230 includes a central processing unit (CPU) or a graphic processing unit (GPU).

The high bandwidth memory 100 may be disposed on the logic die 230, and the high bandwidth memory 100 may be coupled with the logic die 230 by hybrid bonding. The hybrid bonding described for FIG. 1 may be equally applied to the hybrid bonding for FIG. 17. Although FIG. 17 illustrates that one high bandwidth memory 100 is disposed on the logic die 230, a plurality of high bandwidth memories 100 may be disposed on the logic die 230.

The molding material 240 may be disposed on the interposer 220 and may mold the high bandwidth memory 100 and the logic die 230. The molding material 240 may serve to protect and insulate the high bandwidth memory 100 and the logic die 230. In some implementations, the molding material 240 is formed of a thermosetting resin, such as epoxy resin. In some implementations, the molding material 240 is an epoxy molding compound (EMC). In some implementations, the process of molding with the molding material 240 may include a compression molding process or a transfer molding process.

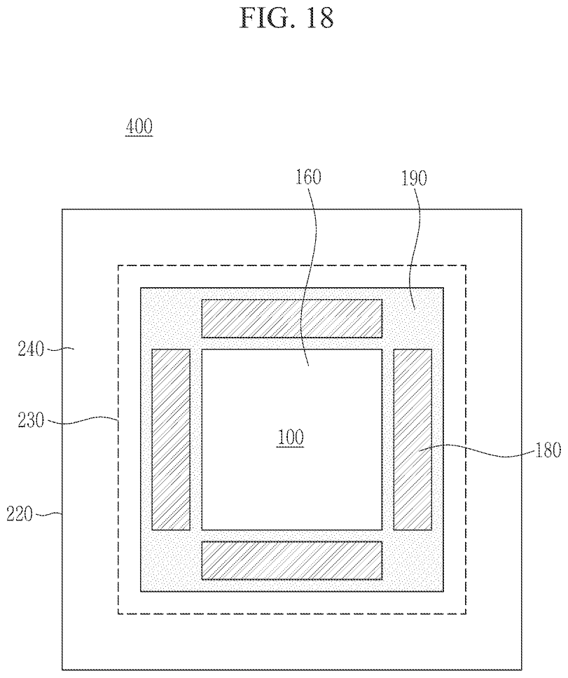

FIG. 18 is a top plan view illustrating a top surface of the 3D semiconductor package 400 including the high bandwidth memory 100 and the logic die 230. In FIG. 18, the high bandwidth memory 100 including the heat dissipation structures 180 may be disposed on the logic die 230. Since the logic die 230 is disposed under the molding material 240, the outline of the logic die 230 is shown as a dotted line. By disposing the heat dissipation structures 180 on the buffer die 110 of the high bandwidth memory 100, the thermal conductivity of the high bandwidth memory 100 may be improved, and the heat generated by the high bandwidth memory 100 may be more easily dissipated. Accordingly, it is possible to improve thermal characteristics of the 3D semiconductor package 400 including the high bandwidth memory 100.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

What is claimed is:

1. A high bandwidth memory structure, comprising:
a buffer die comprising a plurality of conductive lines;
a memory stacking structure on the buffer die, wherein the memory stacking structure comprises a plurality of memory dies that are stacked;
an interconnection structure between the buffer die and the memory stacking structure, wherein the interconnection structure comprises a plurality of connection members and an insulating member surrounding the plurality of connection members; and
a plurality of conductive pads disposed on the buffer die and side by side with the plurality of connection members,
wherein each conductive line of the plurality of conductive lines connects a connection member of the plurality of connection members to a conductive pad of the plurality of conductive pads.

2. The high bandwidth memory structure of claim 1, wherein the plurality of conductive pads include a test pad.

3. The high bandwidth memory structure of claim 1, wherein the plurality of conductive pads are electrically insulated.

4. The high bandwidth memory structure of claim 1, wherein each connection member among the plurality of connection members comprises:
a lower bonding pad; and
an upper bonding pad on the lower bonding pad,
wherein the upper bonding pad is directly bonded to the lower bonding pad.

5. The high bandwidth memory structure of claim 4, wherein the plurality of conductive pads are disposed at the same level as the plurality of lower bonding pads.

6. The high bandwidth memory structure of claim 4, wherein the insulating member comprises:
a lower silicon insulating layer surrounding side surfaces of the plurality of lower bonding pads; and
an upper silicon insulating layer surrounding side surfaces of the plurality of upper bonding pads,
wherein the upper silicon insulating layer is directly bonded to the lower silicon insulating layer.

7. The high bandwidth memory structure of claim 1, wherein the plurality of connection members include a micro-bump.

8. The high bandwidth memory structure of claim 1, wherein the insulating member includes a non-conductive film (NCF).

9. The high bandwidth memory structure of claim 1, wherein the insulating member surrounds a side surface of each conductive pads.

10. A high bandwidth memory structure, comprising:
a buffer die comprising a plurality of conductive lines;
a memory stacking structure on the buffer die, wherein the memory stacking structure comprises a plurality memory dies that are stacked;
an interconnection structure between the buffer die and the memory stacking structure, wherein the interconnection structure comprises a plurality of connection members and an insulating member surrounding the plurality of connection members;
a plurality of conductive pads disposed on the buffer die and side by side with the plurality of connection members, wherein each conductive line of the plurality of conductive lines connects a connection member of the plurality of connection members to a conductive pad of the plurality of conductive pads;
one or more heat dissipation structures disposed on the buffer die and disposed side by side with the memory stacking structure; and
a molding material disposed on the buffer die and molding the memory stacking structure and the one or more heat dissipation structures.

11. The high bandwidth memory structure of claim 10, wherein the one or more heat dissipation structures are disposed on the plurality of conductive pads.

12. The high bandwidth memory structure of claim 10, wherein heat in the memory stacking structure is transferred through the plurality of conductive lines, the plurality of conductive pads, and the one or more heat dissipation structures.

13. The high bandwidth memory structure of claim 10, wherein the one or more heat dissipation structures includes a heat slug.

14. The high bandwidth memory structure of claim 13, further comprising a thermal interface material (TIM) between the buffer die and the heat slug.

15. A method for manufacturing a high bandwidth memory structure, comprising:
forming a plurality of test pads on a buffer die;
stacking a first memory die among N memory dies on the buffer die using a plurality of first connection members, N is greater than or equal to 2, and the plurality of first connection members are disposed side by side with the plurality of test pads;
testing whether a signal is transmitted to a first connection member corresponding to each test pad of the plurality of first connection members using each test pad of the plurality of test pads; and
stacking an n-th memory die on an n-1-th memory die using a plurality of n-th connection members, and testing whether a signal is transmitted to the n-th connection member corresponding to each test pad of the plurality of n-th connection members using each test pad of the plurality of test pads, n is sequentially increased by 1 from 2 and repeated until n=N.

16. The method for manufacturing the high bandwidth memory structure of claim 15, further comprising attaching one or more heat slugs on the plurality of test pads.

17. The method for manufacturing the high bandwidth memory structure of claim 16, further comprising molding the one or more heat slugs and the stacked first to Nth memory dies with a molding material on the buffer die.

18. The method for manufacturing the high bandwidth memory structure of claim 17, further comprising performing a chemical mechanical polishing process (CMP) on the molding material to expose top surface of the one or more heat slugs and a top surface of the stacked first to Nth memory dies.

19. The method for manufacturing the high bandwidth memory structure of claim 15, wherein the stacking of the first memory die of the N memory dies on the buffer die using the plurality of first connection members, and the stacking of the n-th memory die on the n-1-th memory die using the plurality of n-th connection members are performed by hybrid bonding.

20. The method for manufacturing the high bandwidth memory structure of claim 15, wherein the testing whether a signal is transmitted to the first connection member corresponding to each test pad of the plurality of first connection members using each test pad of the plurality of test pads and the testing whether a signal is transmitted to the n-th connection member corresponding to each test pad of the plurality of n-th connection members using each test pad of the plurality of test pads are performed by a probe test.
